(19) United States
(12) Patent Application Publication
(10) Pub. No.: US 2026/0082650 A1
(43) Pub. Date: Mar. 19, 2026

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Takeshi SUWA, Kawasaki Kanagawa (JP); Ryohei NEGA, Yokohama Kanagawa (JP); Kosuke MIURA, Kawasaki Kanagawa (JP)

(21) Appl. No.: 19/020,157

(22) Filed: Jan. 14, 2025

(30) Foreign Application Priority Data
Sep. 13, 2024 (JP) 2024-159372

(51) Int. Cl. H10D 62/85; H10D 30/47; H10D 62/10; H10D 62/852; H10D 64/00; H10D 64/23

(52) U.S. Cl. CPC H10D 62/8503; H10D 30/475; H10D 62/102; H10D 62/852; H10D 64/112; H10D 64/258

(57) ABSTRACT

A nitride semiconductor layer includes a first layer, a second layer, and a p-type semiconductor layer. The p-type semiconductor layer includes a connection part connected with a source electrode, and an extension part extending in a first direction through the nitride semiconductor layer from the connection part. The extension part is positioned between a first interface between the first layer and the second layer, and a second interface between a substrate and the nitride semiconductor layer. An end of the extension part is positioned between a position of an end of a gate electrode at a drain electrode side in the first direction and a position of an end of the drain electrode at the gate electrode side in the first direction.

### CROSS-REFERENCE TO RELATED APPLICATION

This application is based upon and claims the benefit of priority from Japanese Patent Application No. 2024-159372, filed on Sep. 13, 2024; the entire contents of which are incorporated herein by reference.

### FIELD

Embodiments described herein relate generally to a semiconductor device.

### BACKGROUND

HEMTs (High Electron Mobility Transistors) that use gallium nitride materials are known as power devices.

### BRIEF DESCRIPTION OF THE DRAWINGS

FIG. 1 is a schematic cross-sectional view of a semiconductor device of a first embodiment;

FIG. 2 is a schematic cross-sectional view of a semiconductor device of a second embodiment;

FIG. 3 is a schematic cross-sectional view of a semiconductor device of a third embodiment;

FIG. 4 is a schematic cross-sectional view of a semiconductor device of a fourth embodiment;

FIG. 5 is a schematic cross-sectional view of a semiconductor device of a fifth embodiment; and

FIG. 6 is a schematic plan view showing an arrangement of a major configuration of the semiconductor device according to the fifth embodiment.

### DETAILED DESCRIPTION

According to one embodiment, a semiconductor device includes a substrate; a nitride semiconductor layer located on the substrate, the nitride semiconductor layer including a first layer, and a second layer located on the first layer, the second layer having a wider bandgap than the first layer; a source electrode located on the nitride semiconductor layer, the source electrode contacting the nitride semiconductor layer; a drain electrode separated from the source electrode in a first direction, the drain electrode being located on the nitride semiconductor layer, the drain electrode contacting the nitride semiconductor layer; a gate electrode positioned between the source electrode and the drain electrode in the first direction; and an insulating film located between the gate electrode and the nitride semiconductor layer, the nitride semiconductor layer including a p-type semiconductor layer, the p-type semiconductor layer including a connection part connected with the source electrode, and an extension part extending in the first direction through the nitride semiconductor layer from the connection part, the extension part being positioned between a first interface between the first layer and the second layer, and a second interface between the substrate and the nitride semiconductor layer, the extension part not contacting the first interface or the second interface, an end of the extension part separated from the connection part in the first direction being positioned between a position of an end of the gate electrode at the drain electrode side in the first direction and a position of an end of the drain electrode at the gate electrode side in the first direction.

Exemplary embodiments will now be described with reference to the drawings. Similar components in the drawings are marked with like reference numerals.

### First embodiment

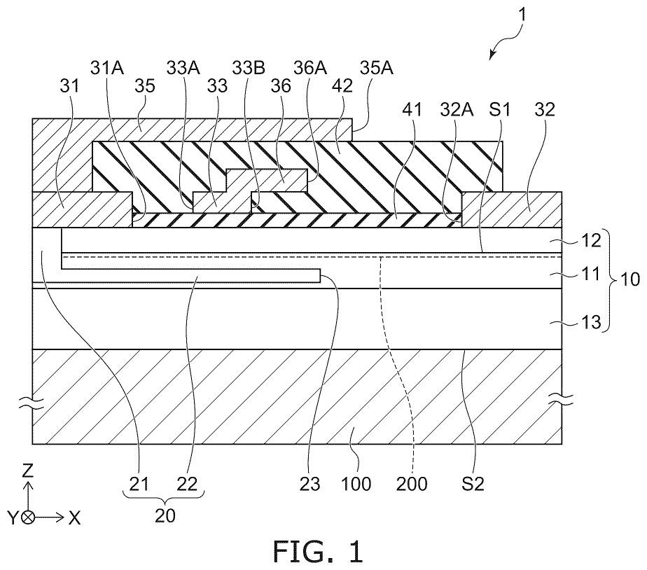

As shown in FIG. 1, a semiconductor device 1 according to a first embodiment includes a substrate 100, and a nitride semiconductor layer 10 located on the substrate 100.

For example, a p-type silicon substrate can be used as the substrate 100. For example, a potential of 0 V may be applied to the substrate 100.

Two directions that cross each other in a plane parallel to a surface of the substrate 100 are taken as a first direction X and a second direction Y. In the example, the first direction X and the second direction Y are orthogonal to each other. A direction that is orthogonal to the first and second directions X and Y is taken as a third direction Z. In the third direction Z, the direction from the substrate 100 toward the nitride semiconductor layer 10 is taken as up. The direction from the nitride semiconductor layer 10 toward the substrate 100 is taken as down.

The nitride semiconductor layer 10 includes a first layer 11, and a second layer 12 located on the first layer 11. In the third direction Z, the first layer 11 is positioned between the substrate 100 and the second layer 12. The bandgap of the second layer 12 is wider than the bandgap of the first layer 11. For example, the first layer 11 is an n-type gallium nitride (GaN) layer; and the second layer 12 is an undoped aluminum gallium nitride (AlGaN) layer. Due to the piezoelectric polarization effect, a two-dimensional electron gas 200 is distributed in the first layer 11 at the vicinity of an interface (first interface) S1 between the first layer 11 and the second layer 12. The thickness of the second layer 12 is less than the thickness of the first layer 11. The first layer 11 may be an undoped GaN layer. The Al and Ga composition ratios in the AlGaN layer of the second layer 12 are arbitrary.

The nitride semiconductor layer 10 may further include a buffer layer 13. The buffer layer 13 is positioned between the substrate 100 and the first layer 11 in the third direction Z. The buffer layer 13 relaxes the lattice mismatch between the substrate 100 and the first layer 11. The buffer layer 13 can be, for example, a GaN layer doped with carbon and/or iron, a superlattice structure of a GaN layer and an AlGaN layer, or a configuration in which the doped GaN layer and the superlattice structure are combined.

The semiconductor device 1 further includes a source electrode 31, a drain electrode 32, and a gate electrode 33 located on the nitride semiconductor layer 10. The source electrode 31, the gate electrode 33, and the drain electrode 32 extend in the second direction Y.

The source electrode 31 and the drain electrode 32 contact the nitride semiconductor layer 10. The source electrode 31 and the drain electrode 32 have ohmic contacts with the nitride semiconductor layer 10. In the example shown in FIG. 1, the source electrode 31 and the drain electrode 32 contact the second layer 12.

The source electrode 31 and the drain electrode 32 are separated from each other in the first direction X. The gate electrode 33 is positioned between the source electrode 31 and the drain electrode 32 in the first direction X. The distance in the first direction X between an end 32A of the drain electrode 32 at the gate electrode 33 side and an end 33B of the gate electrode 33 at the drain electrode 32 side is greater than the distance in the first direction X between an end 31A of the source electrode 31 at the gate electrode 33 side and an end 33A of the gate electrode 33 at the source electrode 31 side.

The semiconductor device 1 further includes an insulating film 41 located between the source electrode 31 and the drain electrode 32 and on the nitride semiconductor layer 10. The insulating film 41 is located between the gate electrode 33 and the nitride semiconductor layer 10; and the gate electrode 33 does not contact the nitride semiconductor layer 10. For example, a silicon nitride film can be used as the insulating film 41.

The semiconductor device 1 further includes a protective film 42. The protective film 42 is located on the insulating film 41 and covers a portion of the source electrode 31 and a portion of the drain electrode 32. The protective film 42 also covers the gate electrode 33. For example, a silicon oxide film or a silicon nitride film can be used as the protective film 42.

The semiconductor device 1 further includes a gate field plate electrode 36 and a source field plate electrode 35. The gate field plate electrode 36 is connected with a portion of the upper surface of the gate electrode 33 and extends through the protective film 42 toward the drain electrode 32 side. The source field plate electrode 35 is connected with the upper surface of the source electrode 31 and extends over the protective film 42 toward the drain electrode 32 side. The gate field plate electrode 36 and the source field plate electrode 35 suppress a current collapse phenomenon.

In the first direction X, the position of an end 36A of the gate field plate electrode 36 at the drain electrode 32 side is positioned between the position of the end 33B of the gate electrode 33 at the drain electrode 32 side and the end 32A of the drain electrode 32 at the gate electrode 33 side. In the first direction X, the position of an end 35A of the source field plate electrode 35 at the drain electrode 32 side is positioned between the position of the end 36A of the gate field plate electrode 36 at the drain electrode 32 side and the position of the end 32A of the drain electrode 32 at the gate electrode 33 side.

The nitride semiconductor layer 10 includes a p-type semiconductor layer 20 that includes, for example, magnesium (Mg) as a p-type impurity. The p-type semiconductor layer 20 includes a connection part 21 connected with the source electrode 31, and an extension part 22 extending in the first direction X through the nitride semiconductor layer 10 from the connection part 21.

The connection part 21 contacts the lower surface of the source electrode 31 and extends downward through the nitride semiconductor layer 10 from the lower surface of the source electrode 31.

The extension part 22 is positioned between a first interface S1 between the first layer 11 and the second layer 12 and a second interface S2 between the substrate 100 and the nitride semiconductor layer 10. In the example shown in FIG. 1, the extension part 22 is positioned inside the first layer 11. The extension part 22 does not contact the two-dimensional electron gas 200 distributed inside the first interface S1 and the first layer 11. Also, the extension part 22 does not contact the second interface S2 between the substrate 100 and the nitride semiconductor layer 10.

The extension part 22 extends from the connection part 21 toward the drain electrode 32 side past the position of the gate electrode 33 in the first direction X. An end 23 of the extension part 22 that is separated from the connection part 21 in the first direction X is positioned between the position of the end 33B of the gate electrode 33 at the drain electrode 32 side and the position of the end 32A of the drain electrode 32 at the gate electrode 33 side in the first direction X. The position in the first direction X of the end 23 of the extension part 22 is between the position in the first direction X of the end 33B of the gate electrode 33 at the drain electrode 32 side and the position in the first direction X of the end 32A of the drain electrode 32 at the gate electrode 33 side. In the first direction X, the end 23 of the extension part 22 is positioned inside the nitride semiconductor layer 10 below the region between the gate electrode 33 and the drain electrode 32.

A current flows between the drain electrode 32 and the source electrode 31 via the two-dimensional electron gas 200 when a first potential (e.g., several hundred V) is applied to the drain electrode 32, a second potential (e.g., 0 V) that is lower than the first potential is applied to the source electrode 31, and a gate voltage that is not less than a threshold is applied to the gate electrode 33; and the semiconductor device 1 is set to an on-state.

When a potential (e.g., about −10 V) that is less than the threshold is applied to the gate electrode 33, the two-dimensional electron gas 200 below the gate electrode 33 is blocked; and the semiconductor device 1 is switched to an off-state.

In the off-state mentioned above, many holes are easily generated inside the nitride semiconductor layer 10 by impact ionization at the vicinity of the end 32A of the drain electrode 32 at which the electric field increases. These holes flow through the nitride semiconductor layer 10 toward the source electrode 31 side and the gate electrode 33 side. In particular, the potential (e.g., about −10 V) of the gate electrode 33 in the off-state is lower than the potential (e.g., 0 V) of the source electrode 31, and so the holes easily accumulate below the gate electrode 33. These holes reduce the effects of the potential of the gate electrode 33 for blocking the two-dimensional electron gas 200; electrons flow from the source electrode 31 toward the drain electrode 32; and positive feedback that promotes the impact ionization at the vicinity of the drain electrode 32 undesirably occurs. The leakage current is increased thereby. Also, the feedback described above generates a large amount of hot carriers, which degrades the reliability.

According to the embodiment, the p-type semiconductor layer 20 that is connected with the source electrode 31 is located inside the nitride semiconductor layer 10, and so the holes generated by impact ionization can be easily discharged to the source electrode 31 via the p-type semiconductor layer 20. As a result, the holes that are generated by the impact ionization can be prevented from accumulating below the gate electrode 33; the leakage current can be reduced; and the reliability can be increased.

According to the embodiment, the extension part 22 of the p-type semiconductor layer 20 is positioned inside the first layer 11 and does not contact the first interface S1 between the first layer 11 and the second layer 12. Also, the extension part 22 does not contact the two-dimensional electron gas 200 distributed inside the first layer 11. As a result, the p-type semiconductor layer 20 does not affect the on-resistance.

The extension part 22 of the p-type semiconductor layer 20 is positioned inside the nitride semiconductor layer 10, without being located in the substrate 100. As a result, compared to when the p-type semiconductor layer 20 is positioned in the substrate 100, the holes that are generated by the impact ionization at the vicinity of the end 32A of the drain electrode 32 can be easily discharged to the source electrode 31 via the p-type semiconductor layer 20.

If the end 23 of the extension part 22 extends to a position at which the end 23 overlaps the drain electrode 32 from below, the breakdown voltage may be reduced. If the end 23 of the extension part 22 does not extend further toward the drain electrode 32 side than the end 33B of the gate electrode 33 at the drain electrode 32 side, the holes that are generated by the impact ionization easily flow toward the gate electrode 33 and easily accumulate below the gate electrode 33. According to the embodiment, the end 23 of the extension part 22 is positioned between the position of the end 33B of the gate electrode 33 at the drain electrode 32 side and the position of the end 32A of the drain electrode 32 at the gate electrode 33 side in the first direction X. As a result, the holes that are generated by the impact ionization can be easily discharged to the source electrode 31 via the p-type semiconductor layer 20 while suppressing the reduction of the breakdown voltage.

To promote the discharge of the holes generated by the impact ionization, it is favorable for the p-type impurity concentration of the p-type semiconductor layer 20 to be not less than 1×10¹⁵ cm⁻³.

Other embodiments will now be described. For the other embodiments, configurations that are different from those of the first embodiment above are mainly described.

### Second embodiment

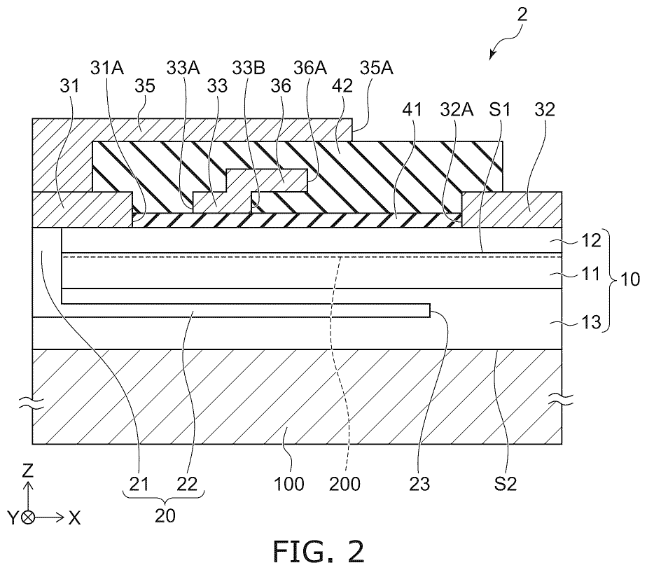

As in a semiconductor device 2 according to a second embodiment shown in FIG. 2, the extension part 22 of the p-type semiconductor layer 20 may be positioned inside the buffer layer 13. The buffer layer 13 is more distant to the end 32A of the drain electrode 32 in the third direction Z than the first layer 11. Accordingly, it is favorable for the end 23 of the extension part 22 positioned inside the buffer layer 13 to be positioned more proximate to the drain electrode 32 in the first direction X than the end of the end 23 of the extension part 22 positioned inside the first layer 11. As a result, the holes that are generated by the impact ionization at the vicinity of the end 32A of the drain electrode 32 can be easily discharged to the source electrode 31 via the p-type semiconductor layer 20.

### Third embodiment

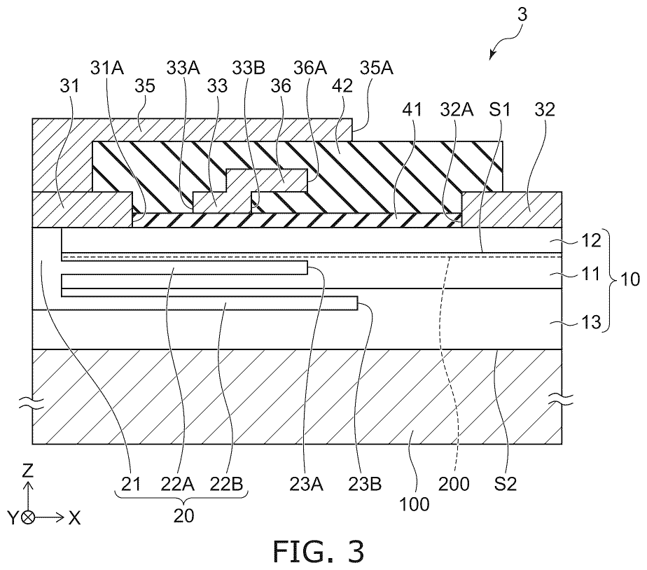

As in a semiconductor device 3 according to a third embodiment shown in FIG. 3, the extension part of the p-type semiconductor layer 20 may include a first extension part 22A positioned inside the first layer 11, and a second extension part 22B positioned inside the buffer layer 13. The first extension part 22A extends in the first direction X through the first layer 11 from the connection part 21; and the second extension part 22B extends in the first direction X through the buffer layer 13 from the connection part 21.

An end 23B of the second extension part 22B separated from the connection part 21 in the first direction X is more proximate to the drain electrode 32 in the first direction X than an end 23A of the first extension part 22A separated from the connection part 21 in the first direction X. As a result, the holes that are generated by the impact ionization at the vicinity of the end 32A of the drain electrode 32 can be easily discharged to the source electrode 31 via the first and second extension parts 22A and 22B.

### Fourth embodiment

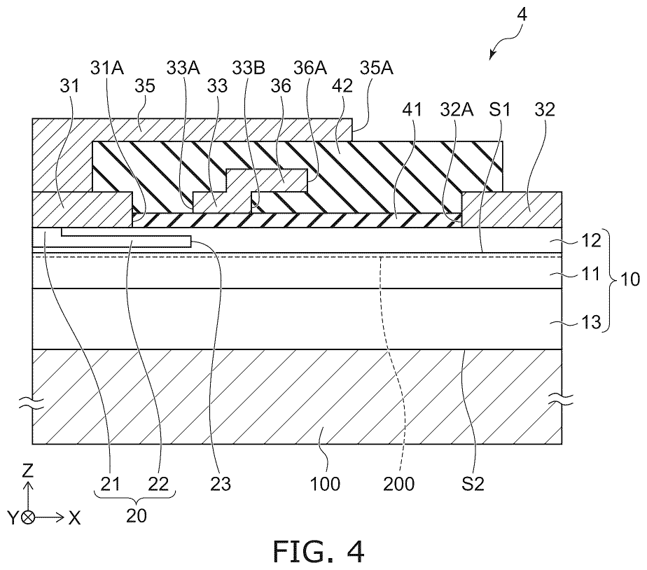

As in a semiconductor device 4 according to a fourth embodiment shown in FIG. 4, the extension part 22 of the p-type semiconductor layer 20 may be positioned inside the second layer 12. The extension part 22 extends in the first direction X through the second layer 12 from the connection part 21. The extension part 22 does not contact the first interface S1 between the first layer 11 and the second layer 12. Also, the extension part 22 does not contact the two-dimensional electron gas 200. As a result, the p-type semiconductor layer 20 does not affect the on-resistance.

The end 23 of the extension part 22 separated from the connection part 21 in the first direction X is positioned between the position of the end 31A of the source electrode 31 at the gate electrode 33 side and the position of the end 33A of the gate electrode 33 at the source electrode 31 side in the first direction X. The position in the first direction X of the end 23 of the extension part 22 is between the position in the first direction X of the end 31A of the source electrode 31 at the gate electrode 33 side and the position in the first direction X of the end 33A of the gate electrode 33 at the source electrode 31 side. In the first direction X, the end 23 of the extension part 22 is positioned inside the nitride semiconductor layer 10 below the region between the source electrode 31 and the gate electrode 33.

The second layer 12 is the uppermost layer of the nitride semiconductor layer 10, and is more proximate to the gate electrode 33 in the third direction Z than the other layers. Because the end 23 of the extension part 22 is at the position described above, the extension part 22 that is positioned inside the second layer 12 does not reduce the effects of the potential of the gate electrode 33 for blocking the two-dimensional electron gas 200. As a result, the semiconductor device 4 can be switched off by controlling the gate electrode 33.

### Fifth embodiment

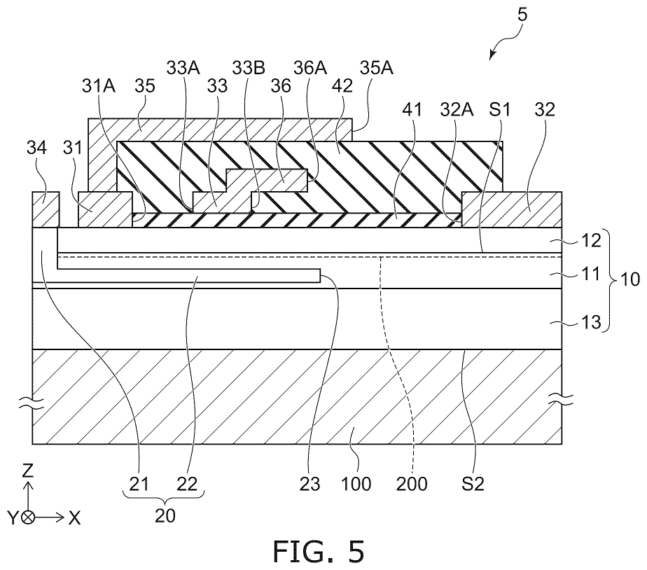

A semiconductor device 5 according to a fifth embodiment shown in FIG. 5 further includes a negative electrode 34 located on the nitride semiconductor layer 10. For example, the negative electrode 34 is located on the second layer 12. A negative potential that is different from the potential of the source electrode 31 is applied to the negative electrode 34.

The connection part 21 of the p-type semiconductor layer 20 is connected with the negative electrode 34 without being connected with the source electrode 31. A lower potential (e.g., −20 V) than the potential applied to the gate electrode 33 in the off-state can be applied to the negative electrode 34. As a result, the discharge of the holes generated by the impact ionization to the negative electrode 34 via the p-type semiconductor layer 20 can be further promoted.

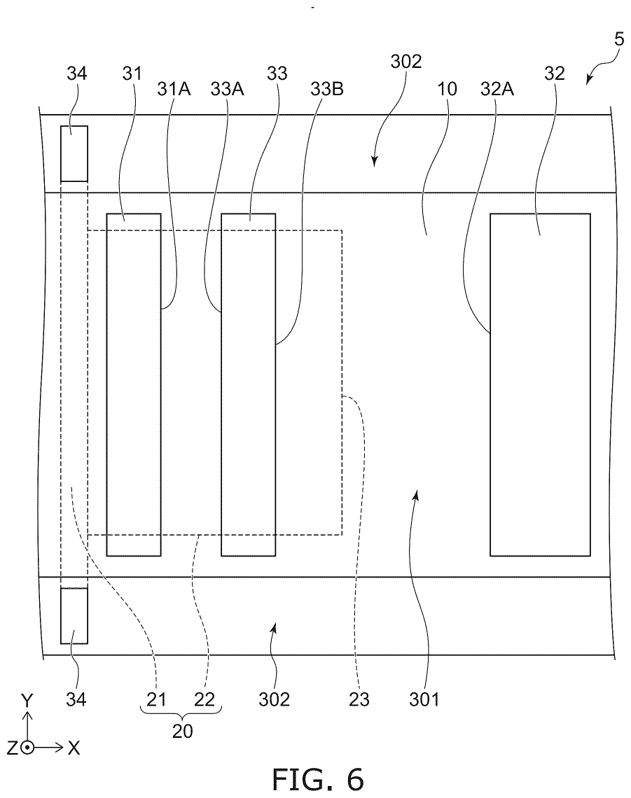

As shown in FIG. 6, for example, the negative electrode 34 is positioned in a termination region 302 outside a cell region 301 in which the source electrode 31, the gate electrode 33, and the drain electrode 32 are located. As a result, the negative electrode 34 does not affect the layout of the source electrode 31, the gate electrode 33, and the drain electrode 32 in the cell region 301. For example, the negative electrodes 34 are located respectively in two termination regions 302 positioned with the cell region 301 interposed in the second direction Y. The connection part 21 of the p-type semiconductor layer 20 is connected with the lower surfaces of the two negative electrodes 34 in the termination regions 302, and extends in the second direction Y. The extension part 22 of the p-type semiconductor layer 20 extends in the first direction X from the connection part 21 and is located in the cell region 301.

The negative electrode 34 may be located on the nitride semiconductor layer 10 in the cell region 301.

Two or more of the embodiments above can be combined as appropriate within the scope of technical feasibility.

For example, the p-type semiconductor layer 20 that is connected with the negative electrode 34 according to the fifth embodiment is applicable to the p-type semiconductor layer 20 of any of the first to fourth embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device, comprising:
a substrate;
a nitride semiconductor layer located on the substrate, the nitride semiconductor layer including
a first layer, and
a second layer located on the first layer, the second layer having a wider bandgap than the first layer;
a source electrode located on the nitride semiconductor layer, the source electrode contacting the nitride semiconductor layer;
a drain electrode separated from the source electrode in a first direction, the drain electrode being located on the nitride semiconductor layer, the drain electrode contacting the nitride semiconductor layer;
a gate electrode positioned between the source electrode and the drain electrode in the first direction; and
an insulating film located between the gate electrode and the nitride semiconductor layer,
the nitride semiconductor layer including a p-type semiconductor layer,
the p-type semiconductor layer including
a connection part connected with the source electrode, and
an extension part extending in the first direction through the nitride semiconductor layer from the connection part,
the extension part being positioned between
a first interface between the first layer and the second layer, and
a second interface between the substrate and the nitride semiconductor layer,
the extension part not contacting the first interface or the second interface,
an end of the extension part separated from the connection part in the first direction being positioned between a position of an end of the gate electrode at the drain electrode side in the first direction and a position of an end of the drain electrode at the gate electrode side in the first direction.

2. The semiconductor device according to claim 1, wherein the extension part is positioned inside the first layer.

3. The semiconductor device according to claim 1, wherein
the nitride semiconductor layer further includes a buffer layer located between the substrate and the first layer, and
the extension part is positioned inside the buffer layer.

4. The semiconductor device according to claim 1, wherein
the nitride semiconductor layer further includes a buffer layer located between the substrate and the first layer,
the extension part includes
a first extension part positioned inside the first layer, and
a second extension part positioned inside the buffer layer, and
an end of the second extension part separated from the connection part in the first direction is positioned more proximate to the drain electrode in the first direction than an end of the first extension part separated from the connection part in the first direction.

5. The semiconductor device according to claim 1, wherein
the extension part does not contact a two-dimensional electron gas distributed inside the first layer.

6. A semiconductor device, comprising:
a substrate;
a nitride semiconductor layer located on the substrate, the nitride semiconductor layer including
a first layer, and
a second layer located on the first layer, the second layer having a wider bandgap than the first layer;
a source electrode located on the nitride semiconductor layer, the source electrode contacting the nitride semiconductor layer;
a drain electrode separated from the source electrode in a first direction, the drain electrode being located on the nitride semiconductor layer, the drain electrode contacting the nitride semiconductor layer;
a gate electrode positioned between the source electrode and the drain electrode in the first direction; and
an insulating film located between the gate electrode and the nitride semiconductor layer,
the nitride semiconductor layer including a p-type semiconductor layer,
the p-type semiconductor layer including
a connection part connected with the source electrode, and
an extension part extending in the first direction through the nitride semiconductor layer from the connection part,
the extension part being positioned inside the second layer,
an end of the extension part separated from the connection part in the first direction being positioned between a position of an end of the source electrode at the gate electrode side in the first direction and a position of an end of the gate electrode at the source electrode side in the first direction.

7. The semiconductor device according to claim 6, wherein
the extension part does not contact a two-dimensional electron gas distributed inside the first layer.

8. A semiconductor device, comprising:
a substrate;
a nitride semiconductor layer located on the substrate, the nitride semiconductor layer including
a first layer, and
a second layer located on the first layer, the second layer having a wider bandgap than the first layer;
a source electrode located on the nitride semiconductor layer, the source electrode contacting the nitride semiconductor layer;
a drain electrode separated from the source electrode in a first direction, the drain electrode being located on the nitride semiconductor layer, the drain electrode contacting the nitride semiconductor layer;
a gate electrode positioned between the source electrode and the drain electrode in the first direction;
an insulating film located between the gate electrode and the nitride semiconductor layer; and
a negative electrode located on the nitride semiconductor layer, a negative potential being applied to the negative electrode,
the nitride semiconductor layer including a p-type semiconductor layer connected with the negative electrode.

9. The semiconductor device according to claim 8, wherein
the p-type semiconductor layer includes
a connection part connected with the negative electrode, and
an extension part extending in the first direction through the nitride semiconductor layer from the connection part,
the extension part is positioned between
a first interface between the first layer and the second layer, and
a second interface between the substrate and the nitride semiconductor layer,
the extension part does not contact the first interface and the second interface, and
an end of the extension part separated from the connection part in the first direction is positioned in a region between a position of an end of the gate electrode at the drain electrode side in the first direction and a position of an end of the drain electrode at the gate electrode side in the first direction.

10. The semiconductor device according to claim 8, wherein
the negative electrode is positioned in a termination region,
the termination region is outside a cell region, and
the source electrode, the gate electrode, and the drain electrode are located in the cell region.

11. The semiconductor device according to claim 8, wherein
the extension part does not contact a two-dimensional electron gas distributed inside the first layer.
